(19) United States
(12) Patent Application Publication
(10) Pub. No.: US 2026/0020415 A1
(43) Pub. Date: Jan. 15, 2026

(54) NORMAL EMITTING STACKED MONOCHROMATIC WAFERS FOR COLOR PIXEL DISPLAYS AND METHODS RELATED THERETO

(71) Applicant: Adeia Semiconductor Bonding Technologies Inc., San Jose, CA (US)

(72) Inventors: Belgacem Haba, Saratoga, CA (US); Rajesh Katkar, Milpitas, CA (US)

(21) Appl. No.: 18/939,223

(22) Filed: Nov. 6, 2024

Related U.S. Application Data
(60) Provisional application No. 63/671,632, filed on Jul. 15, 2024.

(51) Int. Cl. H10H 29/856; H10H 29/41

(52) U.S. Cl. CPC H10H 29/856; H10H 29/41

(57) ABSTRACT

A display device comprises a plurality of substrates comprising a first substrate and a second substrate. The substrates comprise singulated LEDs embedded in a respective dielectric layer. A layer is disposed between the first substrate and the second substrate. The layer comprises mirrors that direct light from respective LEDs of the first substrate towards a display side of the display device.

### CROSS REFERENCE TO RELATED APPLICATION

This application claims the benefit of U.S. Provisional Patent Application No. 63/671,632, filed Jul. 15, 2024, which is hereby incorporated by reference herein in its entirety.

### FIELD

The present disclosure relates to display devices and methods of manufacturing the same.

### BACKGROUND

Micro light emitting diode (microLED, micro-LED, μLED, or μ-LED) displays may provide benefits of higher resolution and increased brightness when compared to conventional display technologies. A typical microLED display may be a heterogeneous system that integrates microLEDs and control devices manufactured using different substrates and different process flows. Unfortunately, current manufacturing processes used to assemble separately manufactured microLEDs and control devices into a single display e.g., robot-aided pick-and-place processes, may be prohibitively expensive and time-consuming for most commercial applications. Accordingly, there exists a need in the art for improved microLED displays and methods of manufacturing the same.

### SUMMARY

Embodiments herein provide for displays or display devices formed from stacked reconstituted monochromatic wafers or substrates and methods for manufacturing the same. In some embodiments, the display or display device is an LED display comprising LEDs of any suitable size such as greater than about 500 microns in size, equal to or less than about 500 microns in size, greater than about 100 microns in size, equal to or less than about 100 microns in size, equal to or less than about 50 microns in size, or equal to or less than about 5 microns in size. In some embodiments, the display or display device is a microLED display (e.g., comprising LEDs equal to or less than about 100 microns, 50 microns, or 5 microns in size). Advantageously, a wafer level process of monochromatic wafer stacking may be used to enable efficient fabrication of an integrated color pixel display from different wafers. The stacking and use of one or more intermediary layers or waveguide layers between the reconstituted wafers or substrates may enable a fill factor of about 50% or any suitable fill factor (e.g., above about 30%, above about 40%, or above about 45%) for the individual LEDs, increasing the fill factor from conventional display devices in which each color may have about 30%, less than about 30%, about 20-25%, or less than about 20-25% of a pixel footprint. A fill factor for an LED may be the size, area, or footprint of an LED to the size, area, or footprint of each pixel of the display. In some embodiments, the fill factor of an LED may be an active area of an LED (e.g., area emitting light) to a pixel area or footprint.

One general aspect includes a method of forming a display or display device by stacking wafers (e.g., reconstituted wafers) and inserting an intermediary layer between the wafers comprising mirrors or dichroic mirrors to direct light emitted by LEDs to a viewing surface of the display device. The wafer level process of monochromatic wafer stacking may enable integrated colored pixels. Advantageously, the stacking of the reconstituted wafers may allow for a higher mass-transfer rate to occur, reducing the time it takes to manufacture a display device.

In some embodiments, a display device comprises a plurality of substrates comprising a first substrate and a second substrate. The first substrate comprises a plurality of singulated first LEDs embedded in a first dielectric layer. The second substrate comprises a plurality of singulated second LEDs embedded in a second dielectric layer. A layer is disposed between the first substrate and the second substrate. The layer comprises mirrors that direct light from respective first LEDs of the first substrate toward a display side of the display. In some embodiments, the display device may be a display, an LED display, a micro-LED display, a micro-LED display device. In some embodiments, the respective LEDs may be micro-LEDs.

In some embodiments, the first substrate is an intermediate substrate and the second substrate is a top substrate. The plurality of substrates further comprises a bottom substrate. The bottom substrate comprises a plurality of singulated third LEDs embedded in a third dielectric layer.

In some embodiments, the mirrors comprise a dichroic film. The dichroic film allows transmission of wavelengths emitted from the singulated LEDs of the bottom substrate while concurrently reflecting wavelengths emitted by the singulated LEDs of the intermediate substrate. The mirrors may comprise pairs of mirrors for each corresponding LED of the intermediate substrate. One mirror of the pair of mirrors may reflect wavelengths emitted from a corresponding LED of the intermediate substrate towards another mirror of the pair of mirrors. The other mirror of the pair of mirrors may reflect light from the one mirror towards the display side of the display device and enables transmission of wavelengths emitted from a corresponding LED of the bottom substrate towards the display side on the display device.

In some embodiments, the LEDs of the bottom substrate may be offset with respect to LEDs in the intermediate and top substrates.

In some embodiments, the layer is a first layer, the mirrors are first mirrors, and the display device further comprises a second layer disposed between the bottom substrate and the intermediate substrate. The second layer may comprise second mirrors that direct light from respective LEDs of the bottom substrate towards the display side of the display device.

In some embodiments, the display device further comprises a third layer disposed on the top substrate comprising third mirrors that direct light from LEDs of the top substrate towards the display side of the display device.

In some embodiments, the first mirrors comprise a dichroic film which allows transmission of wavelengths emitted from the singulated LEDs of the bottom substrate while concurrently reflecting wavelengths emitted from the singulated LEDs of the intermediate substrate.

In some embodiments, the third mirrors comprise a dichroic film which allows transmission of wavelengths emitted from the singulated LEDs embedded in the bottom and intermediate substrates while reflecting wavelengths emitted from the singulated LEDs embedded in the top substrate.

In some embodiments, a second layer is disposed between the bottom substrate and the intermediate substrate. The second layer comprises second mirrors that direct light from respective LEDs of the bottom substrate towards a display side of the display device. Each of the first mirrors are positioned to direct light emitted from the LEDs of the intermediate substrate through a first horizontal direction and each of the second mirrors are positioned to direct light from the LEDs of the bottom substrate through a second horizontal direction orthogonal to the first horizontal direction.

In some embodiments, a plurality of pixels each comprises at least one LED from each of the bottom, intermediate, and top substrates. In some embodiments, each pixel comprises at least three LEDs that each emit a different color of light from the other.

In some embodiments, the display device further comprises a reflective layer disposed between the LEDs and the dielectric layers.

In some embodiments, the dielectric layer comprises a dichroic filter optically tuned material wherein a transmission spectrum of the material overlaps with a respective emission spectra of the respective LED.

In some embodiments, the display device further comprises anti-reflective coatings disposed on top of the respective substrate to enhance light extraction efficiency by reducing internal reflections.

In some embodiments, each of the plurality of substrates is directly bonded to a vertically adjacent substrate and/or layer without use of an intervening adhesive.

Another general aspect includes a method of forming a display (e.g., display device, LED display, LED display device, micro-LED display, micro-LED display device). The method comprises attaching a layer to a first substrate to form a workpiece, and attaching a second substrate to the upper surface of the workpiece. The first substrate comprises a plurality of singulated first LEDs embedded in a first dielectric layer. The second substrate comprises a plurality of singulated second LEDs embedded in a second dielectric layer. The layer comprises mirrors that direct light from first LEDs of the first substrate towards a display side of the display.

In some embodiments, the first substrate is an intermediate substrate, and the second substrate is a top substrate. The method may further comprise attaching a bottom substrate to a lower surface of the workpiece. The bottom substrate may comprise a plurality of singulated third LEDs embedded in a third dielectric layer.

In some embodiments, attaching the layer to the intermediate substrate to form the workpiece comprises aligning the plurality of singulated first LEDs of the intermediate substrate to a respective mirror pair embedded in the first layer so that one mirror of the pair of mirrors reflects wavelengths emitted from a corresponding first LED of the intermediate substrate towards another mirror of the pair of mirrors. In some embodiments, attaching the bottom substrate to the lower surface of the workpiece comprises offsetting the bottom substrate to the workpiece so that the other mirror of the pair of mirrors enables transmission of wavelengths emitted from a corresponding third LED of the bottom substrate towards the display side on the LED display.

In some embodiments, the method further comprises prior to attaching the bottom substrate to the lower surface of the workpiece, attaching a second layer comprising a set of second mirrors to the bottom substrate.

In some embodiments, the method further comprises, before or after attaching the top substrate to the upper surface of the workpiece, attaching a third layer to the top substrate comprising third mirrors that direct light from second LEDs of the top substrate towards the display side of the display device.

In some embodiments, the method further comprises, prior to embedding the plurality of singulated first LEDs in the first dielectric layer, coating a reflective material on non-light-emitting sides of each LED of the plurality of singulated first LEDs.

Another general aspect includes a method of forming a display (e.g., display device, LED display, LED display device, micro-LED display, micro-LED display device). The method comprises attaching a first layer to an intermediate substrate to form a first workpiece, and forming a second workpiece by attaching a second layer comprising a plurality of second mirrors to a bottom substrate to form the second workpiece. The intermediate substrate comprises a plurality of singulated first LEDs embedded in a first dielectric layer. The bottom substrate comprises a plurality of singulated second LEDs embedded in a second dielectric layer. The method further comprises aligning an orientation of the first mirrors of the first workpiece to the second mirrors of the second workpiece to direct light between a first pair of mirrors in the first layer of the first mirrors in a direction orthogonal to light directed between a second pair of mirrors in the second layer of the second mirrors. The method further includes attaching the first workpiece to the second workpiece and attaching a top substrate to the upper surface of the first workpiece, where the top substrate comprises a plurality of singulated third LEDs embedded in a third dielectric layer.

In some embodiments, the method comprises directly bonding each of the substrates to a vertically adjacent substrate and/or layer without use of an intervening adhesive.

### BRIEF DESCRIPTION OF THE DRAWINGS

The above and other objects and advantages of the disclosure will be apparent upon consideration of the following detailed description, taken in conjunction with the accompanying drawings, in which:

FIGS. 1A-1C schematically illustrate example views of a display device, according to some embodiments;

FIGS. 2-3 schematically illustrate example cross section views of a display device, according to some embodiments;

FIGS. 4A-4D schematically illustrate example views of a display device, according to some embodiments;

FIG. 5 schematically illustrates aspects of an example method of forming a display device, according to some embodiments;

FIG. 6 schematically illustrates aspects of an example method of forming a display device, according to some embodiments;

FIG. 7 schematically illustrates forming a portion of display, according to some embodiments; and

FIGS. 8A-8B schematically illustrate hybrid bonding, according to some embodiments.

The figures herein depict various embodiments of the disclosure for purposes of illustration only. It will be appreciated that additional or alternative structures, assemblies, systems, and methods may be implemented within the principles set out by the present disclosure.

### DETAILED DESCRIPTION

Embodiments herein may provide for improved (e.g., more efficient or high-volume) manufacturing of displays (e.g., display devices, LED displays, LED display devices, micro-LED displays, micro-LED display devices) using stacked and bonded reconstituted wafers or substrates. Each reconstituted substrate may include a plurality of singulated LEDs capable of emitting light of a same color (e.g., reconstituted substrate of red LEDs, reconstituted substrate of green LEDs, and reconstituted substrate of blue LEDs) and a layer or waveguide layer between two reconstituted substrates. The waveguide layer comprises mirrors or dichroic mirrors disposed on a corresponding reconstituted substrate. Each waveguide layer may direct light emitted by the LEDs of the corresponding reconstituted substrate to a portion of a pixel area (e.g., active area of a pixel). Advantageously, the stacking of the reconstituted wafers may allow for a higher mass-transfer rate to occur, reducing the time it takes to manufacture a display device (e.g., LED or micro-LED display). The stacking and use of at least one waveguide layer between reconstituted substrates may enable a fill factor of about 50% for the individual LEDs, increasing the fill factor from conventional display devices in which each color may have <30%, less than about 30%, or less than about 20-25% of a pixel footprint.

The integration of microLED technology in displays may offer significant benefits in terms of resolution, energy efficiency, brightness, and overall display performance. The ability to precisely control each microLED may allow for better luminous flux with a higher dynamic range and a broader spectrum of colors, leading to more vibrant, bright, and lifelike images, which may be beneficial for applications requiring high-definition visuals, such as advanced televisions, smartphones, wearable devices, automotives, and virtual/augmented reality devices. Additionally, the energy efficiency of microLEDs may translate into longer battery life for portable devices and lower power consumption for larger displays. The versatility of microLED technology extends to the potential for flexible and transparent displays, opening new avenues for innovative design and application in various fields, ranging from consumer electronics to specialized industrial and medical equipment. MicroLED displays may have higher brightness, increased power efficiency, longer lifetime, more durability, and may be more suitable for stretchable and transparent display applications over light-crystal displays (LCD) or organic light emitting diode (OLED) displays.

However, microLED displays may be costly to fabricate and may have cumbersome and time-consuming manufacturing methods such as robot-aided pick-and-place processes used to transfer large quantity of microLED chips from LED wafer(s) to a display substrate. As an example, a microLED ultra-high density (UHD) 4K RGB (red, green, blue) display may comprise about or at least 25 million microLEDs (e.g., about 8.3 million pixels with each pixel having at least a red microLED, a blue microLED, and a green microLED), and a die bonding machine may transfer between 5 to 10 microLEDs per second, taking approximately 700 hours to transfer 25 million microLED chips for a single display. Accordingly, there exists a need in the art for improved microLED displays with a streamlined mass transfer processes and the methods of manufacturing the same.

LEDs may be fabricated at a first wafer (e.g., 150 mm wafers) and integration with silicon at a second wafer (e.g., 300 mm wafer) may be challenging. Reconstituting LED and silicon separately may help integration and assembly. Different colored LEDs may be fabricated on different wafers (e.g., red LED wafer, green LED wafer, blue LED wafer), singulated (e.g., diced) into individual LEDs (e.g., red LEDs, green LEDs, and blue LEDs), and then transferred (e.g., picked and placed, bonded) onto a display backplane (e.g., transistor matrix, silicon or TFT backplane) to form a display.

In some approaches, R, G, and B wafers may be patterned and vertically stacked. For example, a wafer of patterned blue LEDs may be stacked on top of a wafer of patterned green LEDs, and the wafer of patterned green LEDs may be stacked on top of a wafer of patterned red LEDs. However, the vertically stacked wafers may have LEDs (e.g., surface emitting LEDs) that are overlapping when emitting light, which may be inefficient considering brightness per unit area. The LEDs or substrate may not be transparent to light, and vertically overlapping LEDs may block the light from LEDs underneath. For example, a red LED on bottom may only emit light in areas not occupied by overlapping green and blue LED, and green LED in the intermediate position may only emit light in areas not occupied by overlapping blue LED.

In some approaches, R, G, and B wafers may be reconstituted and vertically stacked. For example, each R, G, and B wafer may be singulated and reconstituted into corresponding R, G, and B reconstituted substrates (e.g., each reconstituted substrate may comprise a plurality of single color LEDs). In the vertically stacked reconstituted substrates, the LEDs may be offset so they are not vertically overlapping and do not block light from LEDs underneath. However, reconstituting and vertically stacking R, G, and B wafers may result in inefficient use of a pixel area. For example, each R, G, and B LED (e.g., surface-emitting LEDs) may have about 30% or less or about 20-25% or less in fill factor (e.g., active area of each LED to a pixel area or footprint). Having a lower fill factor may effectively reduce the brightness of the pixel.

Advantageously, the displays or display devices (e.g., microLED displays) and manufacturing methods described herein may provide for reduced manufacturing costs and manufacturing time compared to conventional pick-and-place manufacturing. Use of use a layer of mirrors and dichroic mirrors to guide light from LEDs may increase size of LEDs in a pixel, thereby increasing the brightness emitted from each pixel.

A size of a pixel for a display may vary depending on the application—about 5 microns or less than about 5 microns, less than about 10 microns, or about 5-10 microns for augmented reality/virtual reality (AR/VR) or mixed reality (MR) applications, about 30-50 microns for watches, about 40-60 microns or about 50-70 microns for cellphones, about 300-400 microns or about 350 microns for computer monitors and screens, about 500-1000 microns or greater than about 0.5 mm for televisions. The size of the source LED occupying the pixel may not match the size of the pixel itself. Light emitted from a small LED can fill all of the pixel area of a large pixel and help create a continuous image. The ratio of pixel size to LED size can range from about 1.5 to 3 in AR/VR or MR applications (e.g., pixel size is about 1.5× LED size to about 3× LED size) to over 100 (e.g., pixel size greater than about 100× LED size) in a television application. The smaller the ratio (e.g., area of pixel to area of LED), the larger the LED fill factor, and more light would be output. A larger LED fill factor indicates higher brightness requirement of the application. Different applications have varying luminous flux density requirement (e.g., brightness requirement). While AR/VR applications require extremely bright light so the projected images may be visible in extreme conditions (e.g., bright daylight), brightness requirements may be less stringent for other applications such as monitors and TVs in which the screens which have a larger viewing distance (e.g., are comparatively far away from an eye of a viewer). In some embodiments, a pixel comprises a plurality of source LEDs (e.g., an RGB pixel comprises 3 LEDs per pixel, an RGBG (red, green, blue, green) pixel comprises four LEDs per pixel), and a control circuit may be shared by several pixels.

The shorter the distance between the screen and viewer (e.g., an eye of a viewer) in an application, the smaller the pixel size requirement to provide a continuous image without a visible gap between the neighboring pixels. In AR/VR or MR applications, where a display may be about 1-2 cm from an eye of a viewer, pixel sizes may be typically less than 5 microns, and there may be a challenge to achieve high pixel density and to ensure uniformity and brightness of pixels for an immersive visual experience. Such applications may require smaller pixels (e.g. <5-10 μm) and larger fill factor. The embodiments herein describe approaches which may enhance the density and uniformity of the pixels and/or improve the light emission efficiency. In television applications where pixel sizes can be greater than 0.5 mm (e.g., the screen is typically several feet away from the eye of a viewer; hence larger pixel and smaller LED fill factor would work), a stacked LED structure may be used for larger pixel requirements. In some embodiments, a pixel may include additional LEDs (e.g., other than RGB, such as white, cyan, magenta, etc.) to achieve an enhanced color gamut beyond the standard RGB and/or to add more light emission to improve brightness.

The reconstitution dielectric stacks may not be optimized for high optical transmission. The low-temperature oxide, dielectric, or polymer dielectric utilized in the reconstitution process, although optically transparent, may not meet optical grade standards, which could lead to scattering losses. The reconstituted wafer may incorporate several inorganic dielectric layers, including multiple layers of silicon oxide, silicon nitride, oxide, or nitride, etc. For instance, the refractive index of SiO₂ is about 1.96, whereas the refractive index of nitride is about 2.1. The refractive index value can vary based on factors such as the deposition process and temperature. An increase in the number of layers and interfaces can lead to greater reflective losses, especially for the light emitted at an angle to the dielectric layers.

In some embodiments, dielectrics specifically tuned to certain color spectrums may be used within the optical path of the display for improved efficiency. Suitable materials for these dielectrics may include polystyrene, cyclic olefin polymer/cyclic olefin copolymers, polycarbonate, PMMA (Acrylic), or Ultraviolet Acrylic. These materials are known for their high transmission in the visible spectrum, which is relevant for improved efficiency and functionality of an RGB display.

As described below, semiconductor substrates, display substrates, LED display substrates, or micro-LED display substrates herein generally have a “device side,” e.g., the side on which semiconductor device elements are fabricated, such as transistors, resistors, capacitors, micro-LEDs, driver circuits, and interconnects, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that form the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active” and “non-active sides” may be used to describe surfaces of material layers or features formed on, in, or through the semiconductor substrate, whether or not the material layers or features are ultimately present in the fabricated or assembled device.

Spatially relative terms are used herein to describe the relationships between elements, such as the relationships between layers and other features described below. Unless the relationship is otherwise defined, terms such as “above,” “over,” “upper,” “upwardly,” “outwardly,” “on,” “below,” “under,” “beneath,” “lower,” and the like are generally made with reference to the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” either alone or in combination with a spatially relevant term include both relationships with intervening elements and direct relationships where there are no intervening elements.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds”. In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bonded to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Direct bonding may include direct dielectric bonding techniques as described herein, and may give rise to direct dielectric bonds. Hybrid bonding may include hybrid bonding techniques as described herein, and may give rise to direct hybrid bonds.

Hybrid bonding methods described herein generally include forming conductive features in the dielectric surfaces of the to-be-bonded substrates, activating the surfaces to open chemical bonds in the dielectric material, and terminating the surfaces with a desired species. In some embodiments, activating the surface may weaken chemical bonds in the dielectric material. Activating and terminating the surfaces with a desired species may include exposing the surfaces to radical species formed in a plasma. In some embodiments, the plasma is formed using a nitrogen-containing gas, e.g., N₂, or forming gas and the terminating species includes nitrogen and hydrogen. In some embodiments, the surfaces may be activated using a wet cleaning process, e.g., by exposing the surfaces to aqueous solutions. In some embodiments, the aqueous solution is tetramethylammonium hydroxide diluted to a certain degree or percentage. In some embodiments, an aqueous solution may be ammonia. In some embodiments, the plasma is formed using a fluorine-containing gas, e.g., fluorine gas or helium containing a small amount of fluorine and/or nitrogen such as about 10% or less by volume, 9% or less, 8% or less, 7% or less, 6% or less, 5% or less, 4% or less, 3% or less, 2% or less, for example 1% or less.

Typically, the hybrid bonding methods further include aligning the substrates, and contacting the activated surfaces to form direct dielectric bonds. After the dielectric bonds are formed, the substrates may be heated to a temperature between 50° C. to 150° C. or more, or of 150° C. or more and maintained at the elevated temperature for a duration of about 1 hour or more, such as between 8 and 24 hours, to form direct metallurgical bonds between the metal features.

As used herein, the term “substrate” means and includes any workpiece, wafer, panel, or article that provides a base material or supporting surface from which or upon which components, elements, devices, assemblies, modules, systems, or features of the devices described herein may be formed. The term substrate also includes display substrates such as glass panels or “semiconductor substrates” that provide a supporting material upon which elements of a semiconductor device are fabricated or attached, and any material layers, features, electronic devices, and/or passive devices formed thereon, therein, or therethrough. For ease of description elements, features, and devices formed therefrom are referred to in the singular or plural but should be understood to describe both singular and plural, e.g., one or more, unless otherwise noted.

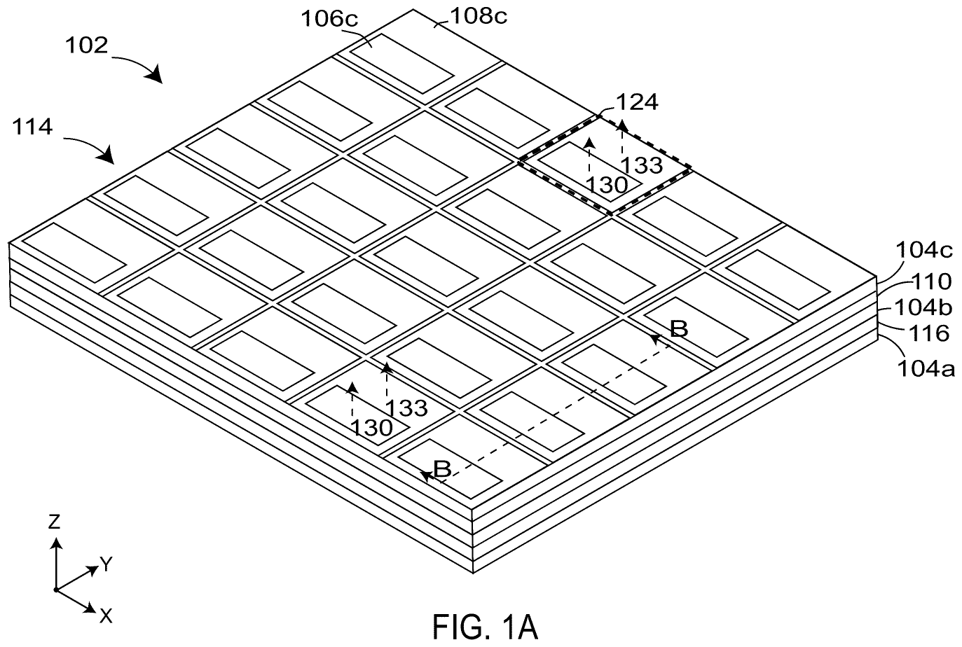

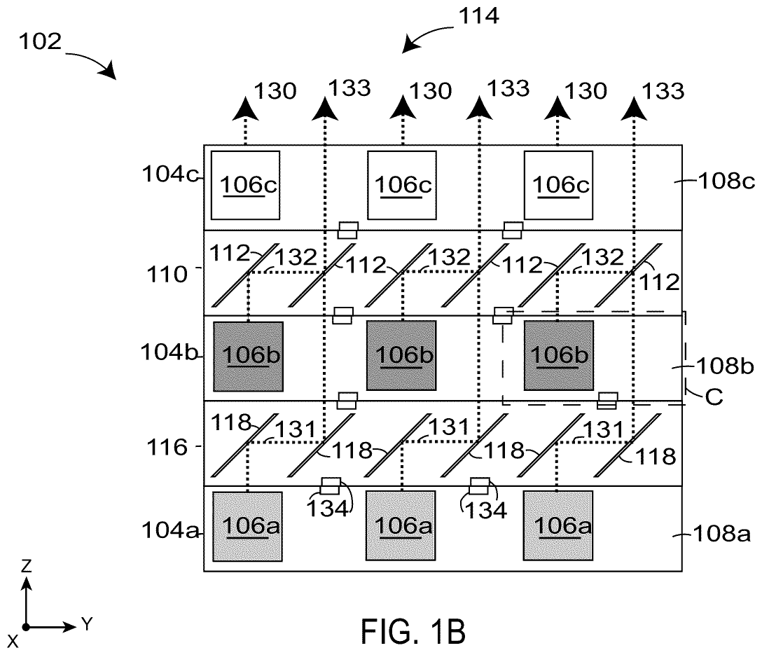

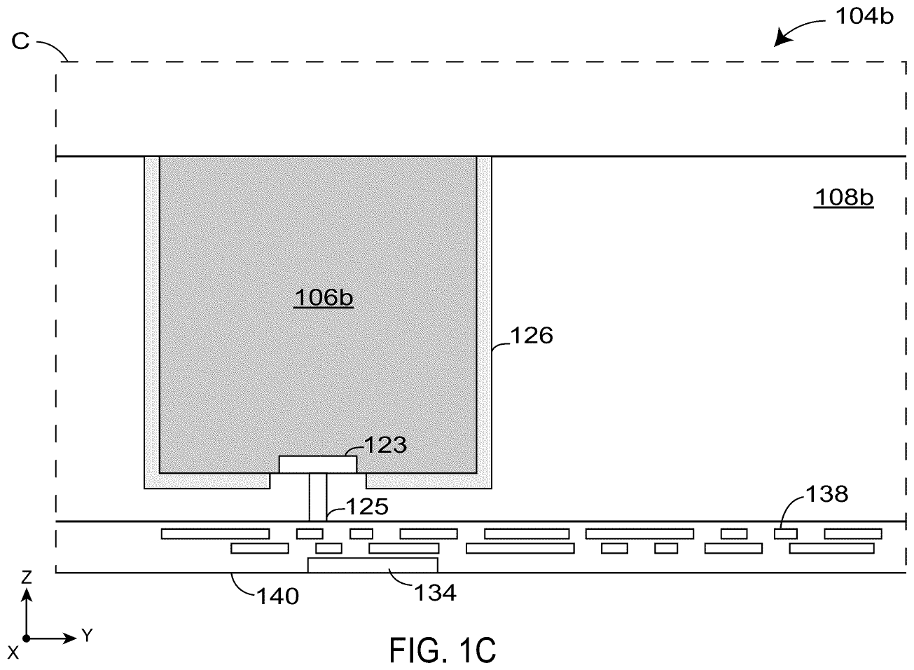

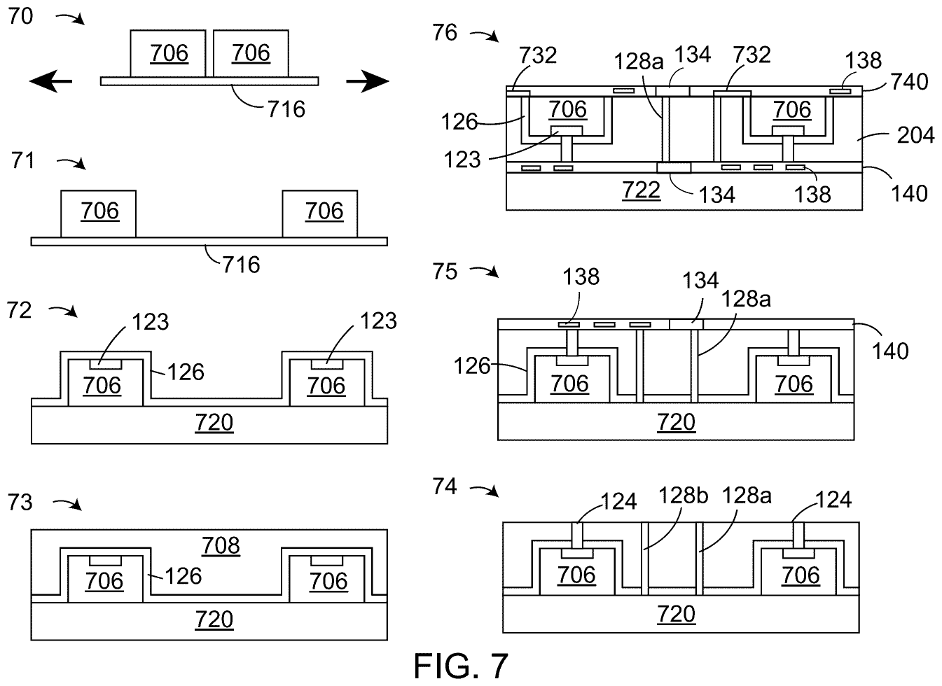

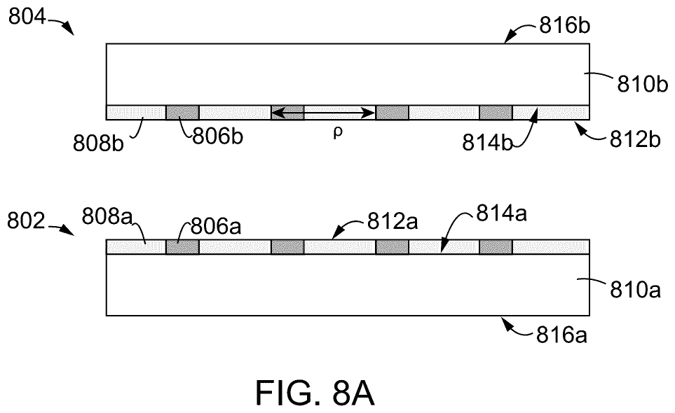

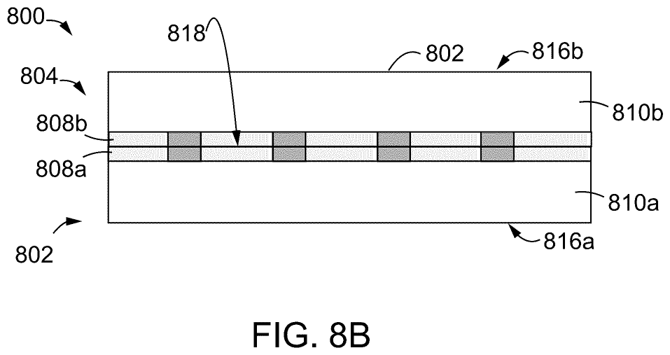

FIGS. 1A-1C, 2, 3, 4A-4D, 5, and 6A-6B schematically illustrate various embodiments of a display. In some embodiments, the display may be a microLED display. For example, the LEDs 106a-c, 406c, and 706 may be microLEDs, with sizes equal to or less than about 100 microns, 50 microns, or 5 microns. The various embodiments of a display may include stacked reconstituted substrates (e.g., comprising singulated LEDs) and at least one intervening waveguide layer (e.g., comprising mirrors) between two reconstituted substrates. Although not explicitly shown in various embodiments of the display in the present disclosure, it will be understood that through substrate vias (TSVs) and/or bond pads may be disposed in or through waveguide layer(s) (e.g., layer 110 or layer 116) or reconstituted substrate(s) (e.g., substrates 104a-c, 404c) to connect a top side to a bottom side of a waveguide layer or reconstituted substrate (e.g., via 128a and/or bond pads 134 shown in FIG. 7 applied to various substrates and layers of the present disclosure) for electrical connectivity of the stacked substrates. FIG. 7 details the method used for spacing LEDs in preparation for a stackable, heterogeneous reconstitution. FIGS. 8A-8B illustrate a hybrid bonding method for bonding substrates (e.g., substrates comprising LEDs to substrates comprising LEDs, substrates comprising LEDs to substrates comprising control devices and/or LEDs).

In some embodiments, the display (e.g., display 102, display 202, display 302, display 402, or any suitable display described throughout the present disclosure) may be an LED display and comprise LEDs greater than about 500 microns in size, or greater than about 100 microns in size. In some embodiments, the methods, systems, and apparatus (e.g., display) described throughout the present disclosure may be applied to any suitable applications such as photo emissive applications (e.g., LED displays, laser arrays, vertical-external-cavity surface-emitting laser (VECSEL) arrays, etc.) photo sensitive applications (e.g., visible imager, short-wave infrared (SWIR) imager, near-infrared (NIR) imager, ultraviolet (UV) imager, etc.) or a combination thereof (e.g., light emitting and/or photo detection application, optical communications application, etc.).

A display may comprise any suitable number of pixels (e.g., one or more pixels, a plurality of pixels). Although a display (e.g., display 102, display 202, display 302, display 402, or any suitable display described throughout the present disclosure) may show a specific number of pixels (e.g., one, three, twenty five, etc.), in some embodiments the display (e.g., display 102, display 202, display 302, display 402, or any suitable display described throughout the present disclosure) may comprise any suitable number of pixels (e.g., hundreds, thousands, millions, etc.).

A pixel may comprise any suitable number, shape, and color of sub-pixels or LEDs (e.g., one, two, three or more LEDs). Although a pixel (e.g., pixel 124, pixel 224, pixel 324, pixel 424, or any suitable pixel described in the present disclosure) may show a specific number of sub-pixels (e.g., three), in some embodiments a pixel (e.g., pixel 124, pixel 224, pixel 324, pixel 424, or any suitable pixel described in the present disclosure) may have any suitable number of sub-pixels or LEDs (e.g., one, two, four, five or more, etc.). Although the sub-pixels or LEDs (e.g., LEDs 106a-c, LED 406c, LED 706, or any suitable LED described in the present disclosure) are shown as similarly shaped rectangles, in some embodiments the sub-pixels or LEDs (e.g., LEDs 106a-c, LED 406c, LED 706, or any suitable LED described in the present disclosure) may be of any suitable shape. In certain embodiments, advancements in color conversion layers (e.g. colored phosphors, quantum dot layers, etc.) may permit the addition of a fourth color, like a green variant or cyan, to enhance the color gamut. In some embodiments, a pixel (e.g., LEDs 106a-c, LED 406c, LED 706, or any suitable LED described in the present disclosure) may comprise four sub-pixels comprising a red LED, a blue LED, and two green LEDs. In some embodiments, LEDs (e.g., LEDs 106a-c, LED 406c, LED 706, or any suitable LED described in the present disclosure) of a pixel (e.g., pixel 124, pixel 224, pixel 324, pixel 424, or any suitable pixel described in the present disclosure) may also be electronically connected to a control device (e.g., singulated integrated circuit, or readout integrated circuits).

FIGS. 1A-1C schematically illustrate various embodiments of a display 102 (e.g., display device, LED display or display device, micro-LED display or display device). FIG. 1A is an isometric top-down view of the display 102. FIG. 1B is a cross sectional view taken along the dotted lines B-B in FIG. 1A. FIG. 1C shows a portion of a cross sectional view of the dotted box C shown in FIG. 1B.

Pixel 124 comprises three sub-pixels or LEDs (e.g., LED 106a, LED 106b, LED 106c). Each sub-pixel or LED may emit a distinct color of light. For example, LEDs 106a, 106b, and 106c may comprise red (R), green (G), and blue (B) LEDs respectively. In another example, LEDs 106a, 106b, and 106c may comprise B, G, and R LEDs respectively. The singulated LEDs 106c disposed in a top substrate 104c may be red LEDs emitting red light. In some embodiments, the red LEDs may comprise a material that emits red light (e.g., aluminum gallium indium phosphide (AlGaInP), aluminum gallium arsenide (AlGaAs), or any suitable material used to generate red light). In some embodiments, the green LEDs may comprise a material that emits green light (e.g., indium gallium nitride (InGaN), gallium phosphide (GaP), or any suitable material used generate green light). In some embodiments, the blue LEDs may comprise a material that emits blue light (e.g., indium gallium nitride (InGaN) or any suitable material used to generate blue light). In some embodiments, a phosphor layer may be used for color conversion in an LED substrate (e.g., AlGaInP). In some embodiments, the singulated LEDs 106c may be green or blue LEDs with a quantum dot layer or phosphor to down convert the green or blue emitted light to red light. The singulated LEDs 106b disposed in the intermediate substrate 104b may be green LEDs and emit green light. The singulated LEDs 106a disposed in the bottom substrate 104a may be blue LEDs and emit blue light.

The display device 102 comprises a plurality of substrates (e.g., a bottom substrate 104a, an intermediate substrate 104b, and a top substrate 104c). Each substrate 104a-c comprises a plurality of LEDs 106a-c (e.g., singulated LEDs) embedded or disposed in a respective dielectric layer 108a-c. The substrates (e.g., substrates 104a-c or any suitable substrate or layer as mentioned in the present disclosure) may comprise any suitable substrate such as those mentioned in the present disclosure. For example the substrates may comprise dummy substrates, passive interposers, passive optical elements (e.g., glass substrates, gratings, lenses), or materials used for base substrate portions 810a, 810b as described in reference to FIG. 8.

In some embodiments, the dielectric layer 108a-c may comprise a transparent oxide. In some embodiments, the respective dielectric layer 108a-c may comprise an oxide material (e.g., silicon oxide), a nitride material, a combination thereof, or any suitable dielectric material. In some embodiments, the dielectric layer 108a-c may comprise an optically tuned dielectric that reduces the absorption of the light transmitted by the LEDs 106a-c. The dielectric layers (e.g., dielectric layers 108a-c, or any suitable layer such as those mentioned in embodiments of the present disclosure) each comprise a dielectric material. The dielectric layers may comprise a same material or different materials. The dielectric material may be any suitable dielectric material such as dielectric materials mentioned in the present disclosure. For example dielectric material may comprise oxides, nitrides, oxynitrides, carbonitrides, and oxycarbonitrides, silicon oxide, silicon nitride, silicon oxynitride, silicon carbonitride, silicon oxycarbonitride, non-conductive material such as a dielectric material or an undoped semiconductor material, such as undoped silicon, which may include native oxide, silicon oxide, silicon nitride, silicon carbide, low K dielectric materials, SiCOH dielectrics, diamond-like carbon or a material comprising a diamond surface. For example the dielectric layers may comprise materials used for bonding layer 808a and 808b of FIG. 8B.

The display device 102 further comprises a plurality of waveguide layers (e.g., first layer 110, and second layer 116). The first layer 110 may disposed on the intermediate substrate 104b and between the top substrate 104c and the intermediate substrate 104b. The second layer 116 may be disposed on the bottom substrate 104a, and between the intermediate substrate 104b and the bottom substrate 104a. Each waveguide layer (e.g., first layer 110 and second layer 116) may comprise optical components such as mirrors (e.g., first mirrors 112 and second mirrors 118). LEDs 106b and LEDs 106a may emit light 132 and light 131 that is guided by the mirrors 112 and 118 respectively to exit a display surface of the display device 102 (e.g., light 133).

Each of the plurality of substrates 104a-c may be directly bonded to a vertically adjacent substrate without the use of an intervening adhesive. In some embodiments, the waveguide layers (e.g., first layer 110 and second layer 116) may be formed on a corresponding substrate (e.g., intermediate substrate 104b and bottom substrate 104a, respectively). In some embodiments the layers and/or substrates may be directly bonded (e.g., hybrid bonded) to a vertically adjacent layer and/or substrate without the use of an intervening adhesive. Additional detail regarding hybrid bonds and hybrid bonding of substrates may be found in the present disclosure, e.g., at least at the description of FIGS. 8A and 8B.

In some embodiments, at least one of or each of the stackable layers (e.g., substrates 104a-c) of a display (e.g., display 102 or any suitable display described throughout the present disclosure such as display 202, display 302, display 402, etc.) may comprise optical components (e.g., LED chips 106a-c, and mirrors) reconstituted in a substrate 104a-c. For example, the mirrors may be formed and included in each substrate 104a-c.

The top-most LEDs 106c is embedded in or disposed in a respective dielectric layer 108c of the top substrate 104c. In some embodiments, the dielectric layer 108c may comprise any suitable dielectric material, such as those mentioned in the present disclosure. In some embodiments, the dielectric layer 108c may comprise an optically tuned dielectric that reduces the absorption of the light transmitted by the LEDs 106a-c. The LEDs 106c may emit light 130 to directly exit a display surface of the display device 102. For example, there may be no intermediary component changing the direction of light emitted from the LED 106c.

The intermediate LEDs 106b is embedded in or disposed in a respective dielectric layer 108b of the intermediate substrate 104b. In some embodiments, the dielectric layer 108c may comprise any suitable dielectric material, such as those mentioned in the present disclosure. In some embodiments, the dielectric layer 108c may comprise an optically tuned dielectric that reduces the absorption of the light transmitted by the LEDs 106a. The intermediate LEDs 106b may emit light 132 that is guided by mirrors 112 to exit a display surface of the display device 102. For example, there may be an intermediary component (e.g., mirrors 112) changing the direction of light 132 emitted from LEDs 106b.

The bottom LEDs 106a is embedded in or disposed in a respective dielectric layer 108a of the intermediate substrate 104a. In some embodiments, the dielectric layer 108c may comprise any suitable dielectric material, such as those mentioned in the present disclosure. The bottom LEDs 106a may emit light 131 that is guided by mirrors 118 to exit a display surface of the display device 102. For example, there may be an intermediary component (e.g., mirrors 118) changing the direction of light 131 emitted from LEDs 106a.

The first layer 110 is disposed between the intermediate substrate 104b and the top substrate 104c. The first layer 110 comprises first mirrors 112 to direct light from respective LEDs 106b of the intermediate substrate 104b towards a display side 114 of the display device 102. In some embodiments, the first mirrors 112 comprise a dichroic film which allows the transmission of wavelengths emitted from the singulated LEDs 106a of the bottom substrate 104a while concurrently reflecting wavelengths emitted from the singulated LEDs 106b of the intermediate substrate 104b.

The second layer 116 is disposed between the bottom substrate 104a and the intermediate substrate 104b. The second layer 116 comprises second mirrors 118 to direct light from respective LEDs 106a of the bottom substrate 104a towards the display side 114 of the display device 102. The second mirrors 118 may not comprise a dichroic film. The second mirrors 118 may comprise a broad band reflecting material (e.g., Al, Ag, Distributed Bragg Reflector (DBR) coatings, etc.,). For example, the second mirrors 118 may not be dichroic mirrors. The second mirrors 118 may be a fully reflective mirror.

FIG. 1B, a dotted box C highlights a zoomed-in view of a portion of the display 102, as shown in FIG. 1C. For example, FIG. 1C shows detailed features such as a reflective layer 126, electrodes 123, connectors 125, and redistribution layer 140 comprising interconnects 138. The features shown in FIG. 1C may be applied to any suitable display (e.g., display 102, display 202, display 302, display 402, or any suitable display described throughout the present disclosure).

FIG. 1C illustrates a detailed view of the dotted box C where sections of a reflective layer 126 is disposed between adjacent LEDs 106b. The reflective layer 126 is disposed or positioned between each LED 106b and a dielectric layer. The reflective layer 126 may comprise a reflective metal or material (e.g., a metal material such as aluminum (Al) silver (Ag) or gold (Au), etc. or a combination thereof) or composite of metals. In some embodiments, the reflective layer 118 may comprise distributed Bragg Reflector (DBR) coatings. The inclusion of the reflective layer 126 may enhance the luminance of the light output from the surface of the display and may also be used to prevent optical cross talk between LEDs 106b. When electrical current flows through a LED 106b, incoherent light is emitted in all directions. A reflective layer 126 enables light emitted towards the reflective layer 126 to be directed towards a viewing surface of the display 102. For example, the reflective layer 126 reflects light emitted from the LED 106b back towards a viewing surface of the display 102, increasing the brightness and contrast of the display 102. In some embodiments, a reflective layer 126 is used in applications where high visibility is relevant, such as outdoor displays or high-definition screens. The reflective layer 126 may serve as a protective barrier for the LEDs 106b from environmental factors and may extend the lifespan of the display. In some embodiments, shape the non-horizontal wall (e.g., sidewalls) of the reflector layer may comprise a parabolic or hyperbolic shape for a parabolic or hyperbolic reflector.

In some embodiments, a light-absorbing layer 120 (not shown) may be disposed or positioned between adjacent LEDs 106b. The light-absorbing layer 120 comprising a light-absorbing material may be disposed between the reflective layer 126 and dielectric layer 108b. The light-absorbing material may significantly reduce optical crosstalk between neighboring LEDs 106b. In some embodiments, the light-absorbing material comprises a metallic, resin, or polymer material.

In some embodiments, the intermediate substrate 104b comprising a plurality of singulated LEDs 106b disposed in a dielectric layer 108b, may include an interconnect layer or redistribution layer 140, such as a redistribution layer (RDL). The electrodes 123 of the LEDs 106b are electrically connected to conductive features (e.g., bond pads 134) via connectors 125 through interconnects 138 in the interconnect layer or redistribution layer 140. The bond pads 134 embedded in a dielectric layer, can be hybrid bonded to bond pads of a control device (e.g., a processor or controller, ROIC, etc.) embedded, in some embodiments, in the layer below what is shown in FIG. 1C. The bond pads 134, electrodes 123, connectors 125, and interconnects 138 may comprise any suitable conductive material. For example, a conductive material may include metals such as copper or copper alloys, nickel, aluminum, or alloys, conductive oxide material such as indium tin oxide (ITO).

In some embodiments, the display device 102 comprises a reflective layer 126 disposed between the LEDs 106a-c and the dielectric layers 108a-c. For example, the structure shown in FIG. 1C can be applied to any suitable substrate of any suitable display (e.g., substrate 104a and 104c of display 102, etc.). In some embodiments, each LED 106a-c may have an electrode 123 in contact with the LED 106a-c. A connector 125 (e.g., contact, via, etc.) may be in direct contact with the electrode 123. The connector 125 may be electrically coupled to a bonding pad (e.g., bond pad 134) through interconnects in the interconnect layer 140 of a respective substrate 104a-c. In some embodiments, the structure shown in FIG. 1C has a via (e.g. through substrate via) connecting the top side to the bottom side of the substrate, although not explicitly shown in FIG. 1C. For example, the substrate 104b and any suitable substrate or layer in the present disclosure may comprise through substrate vias or TSVs (e.g., similar to via 128a between bond pads 134 of FIG. 7) to connect a top side to a bottom side of the substrate or layer for electrical connectivity of the stacked substrates or layers.

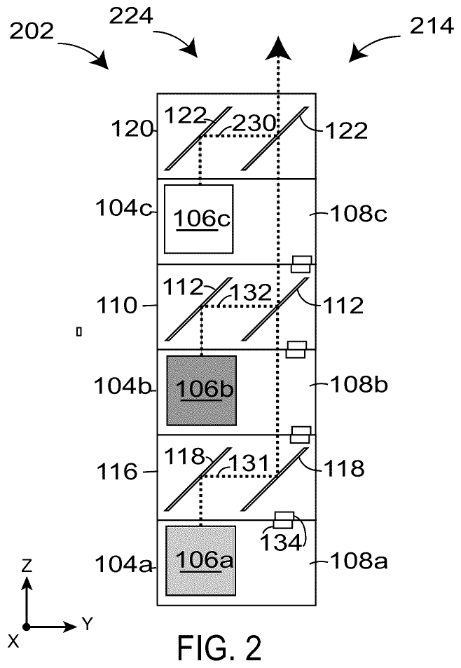

FIG. 2 shows a cross section view of a single pixel 224 for display device 202. The display device 202 may have similar features to the display device 102 described above, and therefore the description of similar features is omitted for brevity. In some embodiments, the display device 202 is the same as display device 102 of FIGS. 1A-1C except a third layer 120 is disposed on the top substrate 104c. The third layer 120 comprises third mirrors 122 that direct light 230 from LEDs 106c of the top substrate 104c towards the display side 214 of the display device 202. It is understood that substrates 104a, 104b, and 104c as well as layers 110 and 116 can have through substrates vias for electrical connectivity from top to bottom.

In some embodiments, light emitted from a single pixel 224 by LEDs 106a-c travel along a same or similar indirect path (e.g., portion of display where light 131, 132, and 230 are reflected by corresponding mirrors 118, 112, and 122 towards a display surface to exit a display). In some embodiments each the stackable layers 108a-c of the display device 202 comprises of optical components (e.g., LED chips 106a-c, and mirrors) reconstituted in a substrate 104a-c.

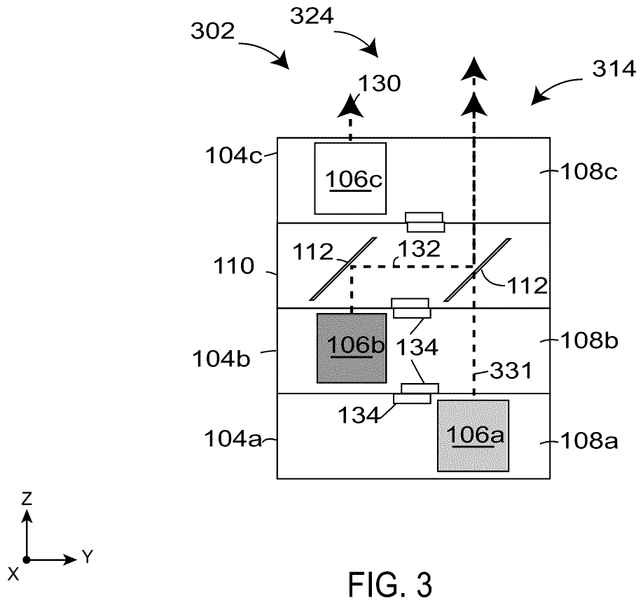

FIG. 3 shows a cross-sectional view of a single pixel 324 of display device 302. The display device 302 may have similar features to the display device 102 described above, and therefore the description of similar features is omitted for brevity. The LED 106a of the bottom substrate 104a is offset with respect to LEDs 106b and 106c in the intermediate substrate 104b and top 104c substrate. This offset enables light 331 emitted from the LED 106a to be transmitted directly towards the display side 314 without having a dedicated reflector layer (e.g. layer 116 and mirrors 118 in FIG. 2). The light 331 emitted from LED 106a passes through the first mirrors 112 (e.g., at least one of a pair of first mirrors 112). The first mirrors 112 (e.g., at least one of a pair of first mirrors 112) may comprise a dichroic film to allow the transmission of wavelengths or light 331 emitted from the singulated LEDs 106a of the bottom substrate 104a while concurrently reflecting wavelengths or light 132 emitted from the singulated LEDs 106b of the intermediate substrate 104b. This offset allows for the removal of the second layer 116 comprising the second mirrors 118 from the display 102 of FIG. 1A to form the display 302 of FIG. 3. In some embodiments, one of a pair of first mirrors 112 may comprise a mirror (e.g., receiving light from LED 106b) and one of a pair of first mirrors 112 may comprise a dichroic film (e.g., receiving light 132 from the other one of the pair of mirrors to reflect towards a surface of a display 302). In some embodiments, both of a pair of first mirrors may comprise a dichroic film.

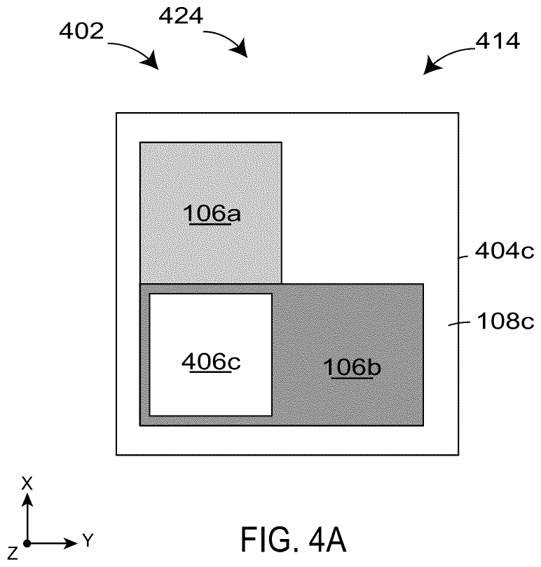

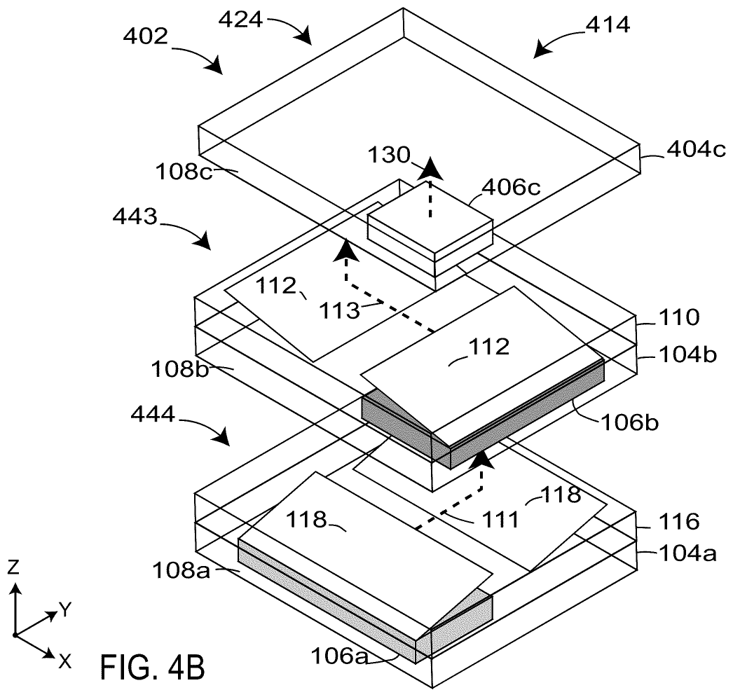

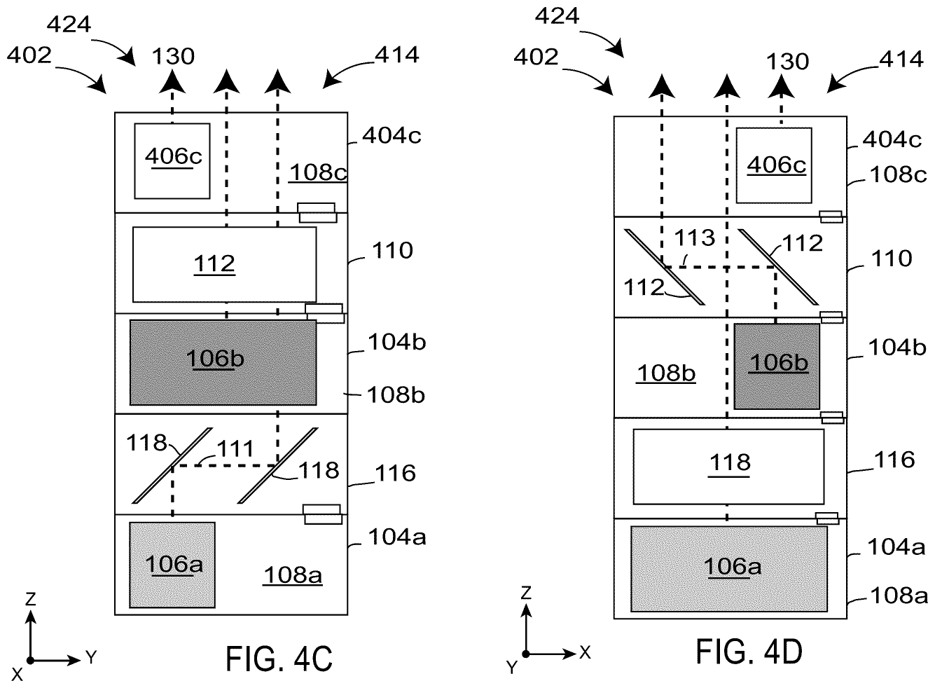

FIGS. 4A-D schematically illustrate example views of a display device 402, according to some embodiments. The display device 402 may have similar features to the display device 102 described above, and therefore the description of similar features is omitted for brevity.

FIG. 4A shows a top-down schematic of a portion of a display device 402 where the bottom LED 106a and intermediate LED 106b are orthogonal to one another, while the top LED 406c is disposed where the two overlap. The display device 402 may be similar to the display device 102 described above, and therefore the description of similar features is omitted for brevity. In some embodiments, the display 402 of FIG. 4A is similar to the display 102 of FIGS. 1A-1C except that the intermediate substrate 104b and corresponding layer 110 may be oriented differently (e.g., orthogonally, rotated in the x-y plane about 90 degrees) to bottom substrate 104a and layer 116, and a top substrate 404c includes an LED 406c which may be smaller in footprint (e.g. about half the size) of LED 106c and in the position where LEDs 106b and 106a overlap in a top down view.

FIGS. 4B-4D are different viewpoints of a portion of the display device 402 in FIG. 4A. FIG. 4B is an isometric view of the display device 402 and shows a plurality of substrates 104a-104b and 404c. The display device 402 comprises a bottom substrate 104a, an intermediate substrate 104b, and a top substrate 404c. Each of the plurality of substrates 104a-b and 404c comprises a plurality of singulated LEDs 106a-b and 406c embedded in a respective dielectric layer 108a-c. The first layer 110 is shown to be disposed on the intermediate substrate 104b or between the intermediate substrate 104b and the top substrate 404c. The second layer 116 is shown to be disposed on the bottom substrate 104a or between the bottom substrate 104a and the intermediate substrate 104b.

The first layer 110 comprises first mirrors 112 that direct light from a respective LED 106b in a first horizontal direction 113 and towards a display side 414 of the display device 402. The second layer 116 comprises second mirrors 118 positioned to direct light emitted from a respective LED 106a a second horizontal direction 111 orthogonal to the first horizontal direction 113.

In some embodiments, the display device 402 further comprises a plurality of pixels 424 each comprising at least one LED 106a-b and 406c from each of the bottom substrate 104a, intermediate substrate 104b, and top substrate 404c. Each pixel 424 may comprise at least three LEDs 106a-b and 406c that each emit a different color of from the other.

The display device 402 may further comprise a reflective layer (e.g., reflective layer 126 as shown in FIG. 1C, applied to any suitable LED of the display device 402) disposed between each LED 106a-b and 406c and the dielectric layer 108a-c. Reflective surfaces or layers of the display device 402 (e.g., the reflective layer 126, the first mirrors 112, second mirrors 118, etc.) may be either a metal reflector, omni-directional reflector, or distributed Bragg reflector (DBR). The mirrors (e.g., first and second mirrors 112 and 118) may comprise of a highly reflective material (e.g., silver, aluminum, etc.).

The display device 402 may have a dielectric layer 108a-c comprising an optically tuned material where the transmission spectra of the material overlap with the respective emission spectra of the respective LEDs 106a-b and 406c. In some embodiments, the display device 402, may have anti-reflective coatings disposed on top of the respective substrate 404a-c to enhance light extraction efficiency by reducing total internal reflection (TIR). Each of plurality of substrates 104a-b and 404c may be bonded (e.g., directly bonded, hybrid bonded) to a vertically adjacent substrate or layer without the use of an intervening adhesive. FIG. 4C and FIG. 4D show different cross-sectional views. In some embodiments, layers or substrates of the display device 402 may comprise optical components (e.g., LED chips 106a-c, and mirrors) reconstituted in a substrate or wafer.

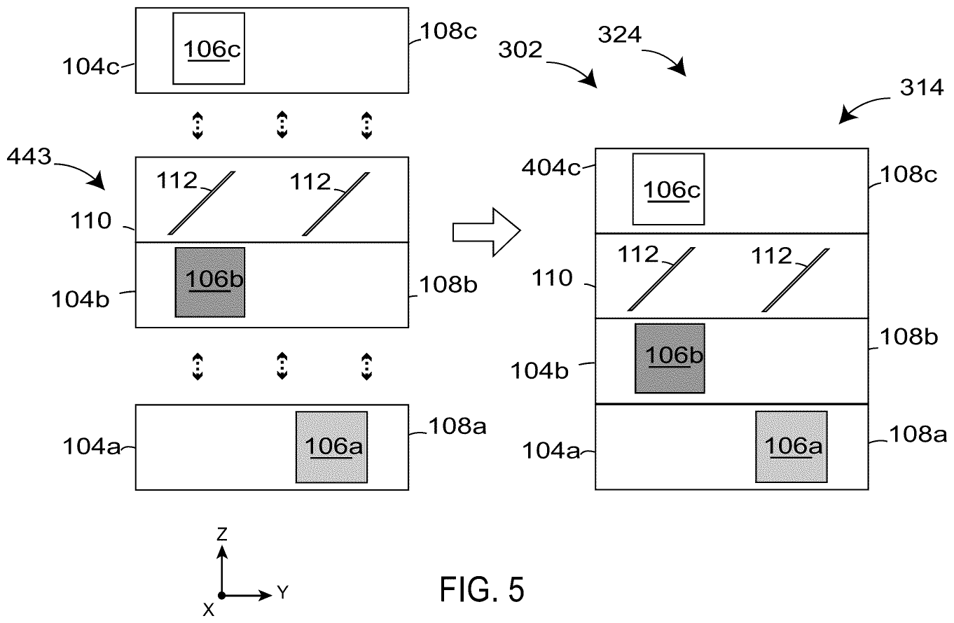

FIG. 5 schematically illustrate aspects of an example method of forming a display device (e.g., display 302 of FIG. 3), according to some embodiments. For example, the method may comprise attaching a layer 110 to an intermediate substrate 104b (e.g., first substrate) to form a workpiece 443, attaching a bottom substrate 104a (e.g., third substrate) to a lower surface of the workpiece 443, and attaching a top substrate 104c (e.g., first substrate) to the upper surface of the workpiece 443. In some embodiments, a first substrate (e.g., intermediate substrate 104b) may comprise a plurality of singulated first LEDs (e.g., LEDs 106b) in a first dielectric layer (e.g., dielectric layer 108b). A second substrate (e.g., top substrate 104c) may comprise a plurality of singulated second LEDs (e.g., LEDs 106c) in a second dielectric layer (e.g., dielectric layer 108c). A bottom substrate 104a may comprise a plurality of singulated third LEDs (e.g., LEDs 106a) in a third dielectric layer (e.g., LEDs 108a).

In some embodiments, attaching the layer 110 to the intermediate substrate 104b to form the workpiece 443 comprises aligning the plurality of LEDs 106b (e.g., singulated first LEDs) of the intermediate substrate 104b to a respective mirror pair 112 embedded in the first layer 110 such that one mirror of the pair of mirrors 112 reflects wavelengths emitted from a corresponding LED 106b of the intermediate substrate 104b towards another mirror of the pair of mirrors 112. In some embodiments, attaching the bottom substrate 104a to the lower surface of the workpiece 443 comprises offsetting the bottom substrate 104a to the workpiece 443 so that the other mirror of the pair of mirrors 112 enables transmission of wavelengths emitted from a corresponding LED 106a (e.g., singulated second LED) of the bottom substrate towards the display side 314 of the LED display 302.

In some embodiments, the method may be applied to form a display 102, display 202, or display 402. For example, the method may further comprise, prior to attaching the bottom substrate 104a to the lower surface of the workpiece 443, attaching a second layer (e.g., layer 116) comprising a set of second mirrors (e.g., mirrors 118) to the bottom substrate 104a.

In some embodiments, the method may be applied to form a display 202. For example, the method may further comprise, before or after attaching the top substrate 104c to the upper surface of the workpiece 443, attaching a third layer 120 to the top substrate 104c comprising third mirrors 122 that direct light from LEDs 106c of the top substrate 104c towards the display side 214 of the display device (e.g., display device 202).

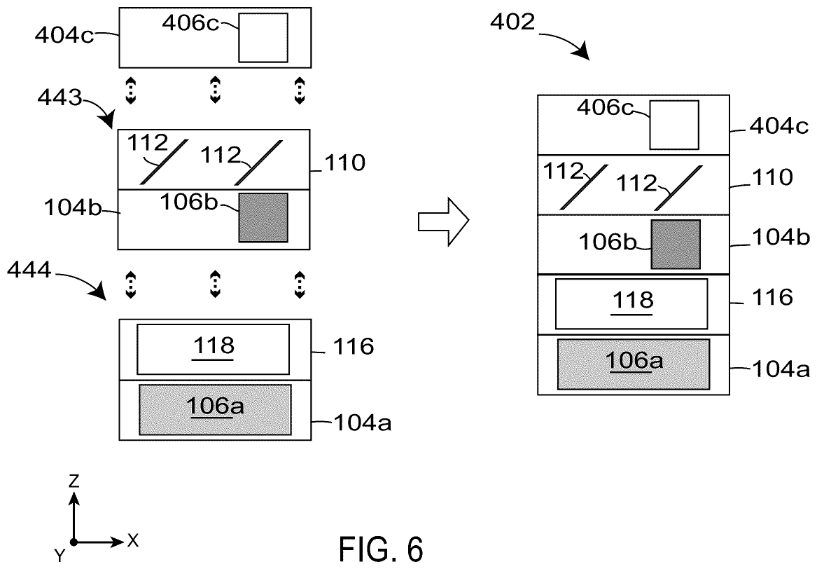

FIG. 6 schematically illustrate aspects of an example method of forming a display device (e.g., display 402 of FIG. 4), according to some embodiments. For example, the method may comprise attaching a first layer 110 to an intermediate substrate 104b (e.g., first substrate) to form a first workpiece 443. The method may further comprise forming a second workpiece 444 by attaching a second layer 116 comprising a plurality of second mirrors 118 to a bottom substrate 104a (e.g., second substrate) to form the second workpiece 444. The method may include bonding top substrate 404c, the first workpiece 444, and the second workpiece 443. In some embodiments, a first substrate (e.g., intermediate substrate 104b) may comprise a plurality of singulated first LEDs (e.g., LEDs 106b) in a first dielectric layer (e.g., dielectric layer 108b). A second substrate (e.g., bottom substrate 104a) may comprise a plurality of singulated second LEDs (e.g., LEDs 106a) in a second dielectric layer (e.g., dielectric layer 108a). A top substrate 404c may comprise a plurality of singulated third LEDs (e.g., LEDs 406c) in a third dielectric layer (e.g., LEDs 108c).

The method may further comprise aligning an orientation of the first mirrors 112 of the first workpiece 443 to the second mirrors 118 of the second workpiece 444 to direct light between a first pair of mirrors 112 in the first layer 110 in a direction orthogonal to light directed between a second pair of mirrors 118 in the second layer 116. The method may further comprise attaching the first workpiece 443 to the second workpiece 444. The method may further include attaching a top substrate 404c to the upper surface of the first workpiece 443. The top substrate 404c may comprise a plurality of LEDs 406c (e.g., singulated third LEDs) embedded in a third dielectric layer 108c.

In some embodiments, the stacking of the first layer 110 on the intermediate substrate 104b, and the stacking of the second layer 116 on the bottom substrate 104a is done optically. In some embodiments, the stacking of the first workpiece 443 and the second workpiece 444 may be done optically, and may be aligned to one another orthogonally.

In some embodiments, the first, second, and third substrate (e.g., substrates 104b, 104c, and 104a or substrates 404c, 104a-b) may comprise singulated LED chips on a wafer assembly, reconstituted in a substrate.

In some embodiments, the method of forming a display (e.g., any suitable display such as those mentioned in the present disclosure) comprises bonding (e.g., directly bonding, hybrid bonding) each of the substrates to a vertically adjacent substrate and/or layer without use of an intervening adhesive.

In some embodiments, the display (e.g., any suitable display such as those mentioned in the present disclosure) may further comprise a brightness enhancement film (BEF). The BEF may manage angular light output from the display device. The BEF may use a prismatic structure to focus light towards on-axis viewers of the display. The BEF may refracts light within the viewing cone (up to 35° off the perpendicular) toward the viewer. Light outside this angle is reflected back and recycled until it exits at the proper angle. The BEF may minimize or reduce coupling to adjacent surfaces. The BEF can be used alone or two BEFs can be crossed, e.g., at 90 degrees to each other. A single sheet or BEF may provide up to 60% increase in brightness and two sheets crossed at 90° can provide up to 120% brightness increase.

In some embodiments, a film or layer (e.g., first layer 110, second layer 116, third layer 120) comprising mirrors may be referred to as a right angle reflector film. The film may comprise a saw tooth reflector coating. The film may be attached or bonded (e.g., directly bonded or hybrid bonded) to on a wafer (e.g, reconstituted R, G, or B wafer or substrate). A wafer may be reconstituted such that pixel pitch is greater than about 2× a pixel size. A thickness of the film or layer may be based on the pixel footprint.

In some embodiments, right angle reflector films (e.g., first layer 110, second layer 116, third layer 120) may be on each of a green, blue, and red reconstituted wafer (e.g., intermediate substrate 104b, bottom substrate 104a, and top substrate 104c) of a display device (e.g., display 204 of FIG. 2). The color emission may be overlapping for each of three wafers (e.g., R, G, and B reconstituted wafers, red, green, and blue light emission may be overlapping). A fill of red, green, or blue LEDs may be about 50% of pixel size or footprint, or may be any suitable fill (e.g., greater than about 30%, greater than about 40%, greater than about 45%).

In some embodiments, right angle reflector films (e.g., first layer 110, second layer 116) may be on green reconstituted wafer and blue reconstituted wafers (e.g., intermediate substrate 104b, bottom substrate 104a) of a display device (e.g., display 102 of FIGS. 1A-1B, display 402 of FIG. 4B, etc.). For example, a red reconstituted wafer (e.g., top substrate 104c, 404c) may be stacked on a green reconstituted wafer (e.g., intermediate substrate 104b) and a blue reconstituted wafer (e.g., bottom substrate 104a). Light emission from LEDs of a red reconstituted wafer may not overlap light emission from LEDs of a green and blue reconstituted wafer. Light emission from LEDs of green and blue reconstituted wafers may overlap. For example, a reflector film on a green reconstituted wafer (e.g., between a red reconstituted wafer and blue reconstituted wafer) may be a dichroic film tuned to reflect green light and transmit blue light. A reflector film on a blue reconstituted wafer may comprise a reflective layer that is tuned to reflect blue light, or may be a full mirror. A fill of red, green, or blue LEDs may be 50% of pixel size or footprint or any suitable fill (e.g., red may have greater than about 50% and green and blue may have less than about 50%, green and blue may have greater than about 50% and red may have less than about 50%, etc.).

In some embodiments, a right angle reflector film (e.g., first layer 110) may be on a green reconstituted wafer (e.g., intermediate substrate 104b) of a display device (e.g., display 302 of FIG. 3). For example, a blue reconstituted wafer (e.g., bottom substrate 104a) and a red reconstituted wafer (e.g., top substrate 104c) may comprise surface-emitting LEDs, and a green reconstituted wafer (e.g., intermediate substrate 104b) with a reflector film (e.g., first layer 110) bonded to the green reconstituted wafer may be between the blue reconstituted wafer and the red reconstituted wafer. The red reconstituted wafer may be closest to a viewing surface of a display device. Position of LEDs of a red and blue reconstituted wafer may be offset from each other (e.g., in a horizontal direction). A position of LEDs of a green and blue reconstituted wafer may overlap (e.g., in a vertical direction). An emission of green and blue light from green and blue reconstituted wafers may be overlapping. A reflector film on a green reconstituted wafer (e.g., between a red reconstituted wafer and blue reconstituted wafer) may be a dichroic film tuned to reflect green light and transmit blue light.

Although embodiments in the present disclosure may refer to a reconstituted wafer comprising LEDs of a particular color (e.g., red, green, or blue), any suitable color may be used (e.g., colors may be different). Although embodiments in the present disclosure may describe three reconstituted wafers (e.g., substrates 104a-104c, substrates 104a-b, 404c) in a display device, any suitable number of reconstituted wafers may be used (e.g., one, two, three or more). Although embodiments in the present disclosure may describe displays comprising a particular number of layers (e.g., layers 110, 116) in a display device, in some embodiments any suitable number of layers may be used (e.g., one, two or more). Although embodiments in the present disclosure may describe displays comprising LEDs of a particular color in a particular layer or substrate, in some embodiments a display may have any suitable arrangement of stacked substrates (e.g., top substrate comprises blue LEDs, intermediate substrate comprises green LEDs, and bottom substrate comprises red LEDs, etc.). In some embodiments, a mirror may be a full mirror or a dichroic mirror. In some embodiments, where light emission of LEDs overlaps in a vertical dimension, a dichroic mirror may be used. In some embodiments, where there is no overlap of different colored lights, a full mirror may be used. It is contemplated that any combination of the methods described above may be used to form a display whether or not expressly recited herein.

FIG. 7 shows a schematic of an example method to form a display through heterogenous pixel integration, where singulated LED 706 from RGB wafers can be integrated to form a composite RGB pixel. In some embodiments, the example method shows forming a substrate (e.g., substrates 104a, 104b, 104c, 404c). In some embodiments, singulated LED 706 may correspond to (e.g., be similar to or same as) LEDs 106a-c, LED 406c, LED 706, or any suitable LED described in the present disclosure.

At block 70, the method includes singulating a wafer to form pixel-size chips or chiplets. For example, a wafer of singulated LEDs 706 may be placed on a tape frame or temporary carrier 716 and singulated to form LED chips or chiplets. The singulated LED chips or chiplets may be about 1×1 micron², about 5×5 micron², about 10×10 micron², to about 40×40 micron² or any suitable LED size for a pixel. In some embodiments, any suitable wafer (e.g., wafer of blue LEDs, wafer of green LEDs, wafer of any suitable color, etc.) may be placed on a tape frame and singulated. The method may further include stretching the temporary carrier 716 to space apart neighboring chips or LEDs (e.g., singulated LEDs 706), shown at 704.

At block 71, the method includes spacing apart singulated chips or chiplets. In some embodiments, the method of spacing singulated LED chips (e.g., singulated LEDs 706) from diced wafers may include separation via dicing tape expansion (e.g., stretching temporary carrier 716). For example, the temporary carrier 716 may be stretched to create uniform spacing between neighboring singulated LEDs (e.g., singulated LEDs 706). A spacing of about 1 to 40 microns between neighboring singulated LEDs (e.g., singulated LEDs 706) may be formed as based on a desired pixel size. In some embodiments, after stretching the chiplets on a first tape, the spaced-apart chiplets may be transferred to a second tape for a second stretching operation. Multiple stretching operations may be performed to obtain the desired lateral spacing between the chiplets before subsequent operations. One of the subsequent operations may comprise transferring the chiplets to a carrier.

At block 72, the method includes transferring the singulated chips or chiplets to a carrier substrate. For example, singulated LEDs 706 are transferred to a carrier substrate 720 via bonding or adhesive. Before or after transferring, diffusion regions may be removed from the LEDs and first electrodes 123 may be formed. In some embodiments, both electrodes (e.g., first and second electrodes) may be formed to the LEDs based on the design. The method may include forming a reflective layer 126 over the plurality of singulated LED (e.g., singulated LEDs 706). The reflective layer 126 may comprise a reflective metal (e.g., Ag, Au, or Al, etc.) or DBR coatings. One or more dielectric layers (e.g., adhesion, isolation, passivation, barrier, etc.) may be deposited before and/or after the reflective layer 126 is formed. In some embodiments, the reflective layer may comprise of a distributed Bragg reflector. In some embodiments, a reflective material (e.g., reflective layer 126) may be coated on non-light-emitting sides of each LED 706. In some embodiments, a light-absorbing layer may be disposed or positioned between adjacent LEDs 706. The light-absorbing layer comprising a light-absorbing material may be disposed between the reflective layer 126 and a dielectric layer 708. The light-absorbing material may significantly reduce optical crosstalk between neighboring LEDs 706. In some embodiments, the light-absorbing material comprises a metallic, resin, or polymer material.

At block 73, the method includes forming a reconstitution dielectric over the singulated chips or chiplets. For example, the dielectric layer 708 is formed over the reflective layer 126. The dielectric layer 708 may comprise silicon oxide or a suitable dielectric material tuned to transmit a specific wavelength range (e.g., corresponding to a color of light emitted from an LED of bonded adjacent substrate behind/below dielectric layer 708). In some embodiments, the dielectric layer 708 may correspond to (e.g., be the same or similar to) dielectric layers 108a-c.

At block 74, the method includes forming electrical connectors to the chip or chiplets. For example, electrical connectors 125 are formed to contact the electrodes 123 of singulated LEDs 706. The method may include forming vias 128a and 128b through the dielectric layer 708. The vias 128a-b may enable electrical connections through the dielectric layer 708 to neighboring substrates via hybrid bonding. The electrical connectors 125 and vias 128a-b may comprise a same or different material and may be any suitable conductive material such as those described in the present disclosure. In some embodiments, the method of forming the electrical connectors 125 and vias 128a-b may comprise depositing or coating a suitable adhesion layer over a patterned cavity corresponding to the electrical connector 125 and/or vias 128a-b, over filling the patterned cavity with a suitable conductive layer, and planarizing the conductive layer to remove unwanted materials (e.g., overburden of material, excess material, a portion of material to help planarize a surface). The unwanted materials may comprise portions of the conductive layer, the adhesion layer, and the dielectric layer 708. In some embodiments, the connectors 125 and vias 128a-b may comprise wirebonds, formed by wirebonding operations. In other embodiments, the connectors 125 and vias 128a-b may be formed by 3D printing methods or screen printing methods.

At block 75, the method includes forming a direct bonding interface (DBI) layer (e.g., bottom DBI layer). For example, the method comprises forming a redistribution layer 140 comprising conductive features or bond pads 134 and interconnects 138 in a dielectric layer.

At block 76, the method includes transferring the reconstituted wafer to another substrate. For example, the method includes transferring the reconstituted singulated singulated LEDs 706 and redistribution layer 140 to substrate 722 (e.g., another carrier or a target wafer) and removing the first carrier 720. In some embodiments, the reconstituted wafer comprising singulated singulated LEDs 706 can be transferred to or hybrid bonded to another reconstituted wafer (comprising LEDs and/or control device) or another wafer comprising control devices (e.g., control or controller device wafer, device wafer, ROIC wafer, full wafer, etc.). The method may include forming second electrodes 732 of the LEDs 706. The method may include forming another DBI layer (e.g., top DBI layer). For example, the method includes forming a redistribution layer 740 comprising interconnects 138 and bond pads 134 in a dielectric layer.

In some embodiments, the method shown in FIG. 7 can be modified to form any suitable substrates such as those mentioned in the present disclosure. For example, at block 76, method may include multiple transfer steps, where different types of LEDs (e.g., singulated wafer of red LEDs, singulated wafer of green LEDs, singulated wafer of blue LEDs, etc.) and/or singulated control devices may be transferred.

In some embodiments, the method includes hybrid bonding to electrically connect each control device to one or more of the LEDs to form a pixel. For example, at block 74 the substrate 722 may be a target substrate and the reconstituted wafer may be a substrate (e.g., one of the substrates 104a-c, 404c). For example, the substrate 104a may be hybrid bonded to additional substrates (e.g., via redistribution layer 740) and the substrate 104a may be hybrid bonded to a processor substrate, reconstituted substrate or wafer, etc. (e.g., via redistribution layer 140). Hybrid bonding the substrate 104a to a processor substrate may electrically connect a control device to one or more LEDs of the second substrates. Each control device and the one or more LEDs electrically connected thereto may form a pixel.

In some embodiments, where there are more than one stacked layer, the display may further comprise light guides. For example, the method may include forming deep-trench isolation with metal fill that guides light emitted from the LEDs of at least of the first substrates or the second substrate to a surface of the display. For example, the method may include forming channels with metal coatings to form light guides. In some embodiments, the method may include forming a dielectric fill on the metal coatings in the channels.

Various embodiments disclosed herein relate to directly bonded structures in which two or more elements can be directly bonded to one another without an intervening adhesive. Such processes and structures are referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 808a and/or 808b can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, and U.S. patent application Ser. No. 18/391,173, filed Dec. 20, 2023, the entire contents of each of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 8A and 8B schematically illustrate cross-sectional side views of first and second elements 802, 804 prior to and after, respectively, a process for forming a directly bonded structure, and more particularly a hybrid bonded structure, according to some embodiments. In FIG. 1B, a bonded structure 800 comprises the first and second elements 802 and 804 that are directly bonded to one another at a bond interface 818 without an intervening adhesive. Conductive features 806a of a first element 802 may be electrically connected to corresponding conductive features 806b of a second element 804. In the illustrated hybrid bonded structure 800, the conductive features 806a are directly bonded to the corresponding conductive features 806b without intervening solder or conductive adhesive.

The conductive features 806a and 806b of the illustrated embodiment are embedded in, and can be considered part of, a first bonding layer 808a of the first element 802 and a second bonding layer 808b of the second element 804, respectively. Field regions of the bonding layers 808a, 808b extend between and partially or fully surround the conductive features 806a, 806b. The bonding layers 808a, 808b can comprise layers of non-conductive materials suitable for direct bonding, as described above, and the field regions are directly bonded to one another without an adhesive. The non-conductive bonding layers 808a, 808b can be disposed on respective front sides 814a, 814b of base substrate portions 810a, 810b.

The first and second elements 802, 804 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 802, 804, and back-end-of-line (BEOL) interconnect layers over such semiconductor portions. The bonding layers 808a, 808b can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 810a, 810b, and can electrically communicate with at least some of the conductive features 806a, 806b. Active devices and/or circuitry can be disposed at or near the front sides 814a, 814b of the base substrate portions 810a, 810b, and/or at or near opposite backsides 816a, 816b of the base substrate portions 810a, 810b. In other embodiments, the base substrate portions 810a, 810b may not include active circuitry, but may instead comprise dummy substrates, passive interposers, passive optical elements (e.g., glass substrates, gratings, lenses), etc. The bonding layers 808a, 808b are shown as being provided on the front sides of the elements, but similar bonding layers can be additionally or alternatively provided on the back sides of the elements.

In some embodiments, the base substrate portions 810a, 810b can have significantly different coefficients of thermal expansion (CTEs), and bonding elements that include such different based substrate portions can form a heterogenous bonded structure. The CTE difference between the base substrate portions 810a and 810b, and particularly between bulk semiconductor (typically single crystal) portions of the base substrate portions 810a, 810b, can be greater than 5 ppm/° C. or greater than 10 ppm/° C. For example, the CTE difference between the base substrate portions 810a and 810b can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 810a, 810b can comprise optoelectronic single crystal materials, including perovskite materials, that are useful for optical piezoelectric or pyroelectric applications, and the other of the base substrate portions 810a, 810b comprises a more conventional substrate material. For example, one of the base substrate portions 810a, 810b comprises lithium tantalate (LiTaO₃) or lithium niobate (LiNbO₃), and the other one of the base substrate portions 810a, 810b comprises silicon (Si), quartz, fused silica glass, sapphire, or a glass. In other embodiments, one of the base substrate portions 810a, 810b comprises a III-V single semiconductor material, such as gallium arsenide (GaAs) or gallium nitride (GaN), and the other one of the base substrate portions 810a, 810b can comprise a non-III-V semiconductor material, such as silicon (Si), or can comprise other materials with similar CTE, such as quartz, fused silica glass, sapphire, or a glass. In still other embodiments, one of the base substrate portions 810a, 810b comprises a semiconductor material and the other of the base substrate portions 810a, 810b comprises a packaging material, such as a glass, organic or ceramic substrate.

In some arrangements, the first element 802 can comprise a singulated element, such as a singulated integrated device die. In other arrangements, the first element 802 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 804 can comprise a singulated element, such as a singulated integrated device die. In other arrangements, the second element 804 can comprise a carrier or substrate (e.g., a semiconductor wafer). The embodiments disclosed herein can accordingly apply to wafer-to-wafer (W2W), die-to-die (D2D), or die-to-wafer (D2W) bonding processes. In W2W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 802, 804 are shown, any suitable number of elements can be stacked in the bonded structure 800. For example, a third element (not shown) can be stacked on the second element 804, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 802. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 808a, 808b, the bonding layers 808a, 808b can be prepared for direct bonding. Non-conductive bonding surfaces 812a, 812b at the upper or exterior surfaces of the bonding layers 808a, 808b can be prepared for direct bonding by polishing, for example, by chemical mechanical polishing (CMP). The roughness of the polished bonding surfaces 812a, 812b can be less than 30 Å rms. For example, the roughness of the bonding surfaces 812a and 812b can be in a range of about 0.1 Å rms to 15 Å rms, 0.5 Å rms to 10 Å rms, or 1 Å rms to 5 Å rms. Polishing can also be tuned to leave the conductive features 806a, 806b recessed relative to the field regions of the bonding layers 808a, 808b.

Preparation for direct bonding can also include cleaning and exposing one or both of the bonding surfaces 812a, 812b to a plasma and/or etchants to activate at least one of the surfaces 812a, 812b. In some embodiments, one or both of the surfaces 812a, 812b can be terminated with a species after activation or during activation (e.g., during the plasma and/or etch processes). Without being limited by theory, in some embodiments, the activation process can be performed to break chemical bonds at the bonding surface(s) 812a, 812b, and the termination process can provide additional chemical species at the bonding surface(s) 812a, 812b that alters the chemical bond and/or improves the bonding energy during direct bonding. In some embodiments, the activation and termination are provided in the same step, e.g., a plasma to activate and terminate the surface(s) 812a, 812b. In other embodiments, one or both of the bonding surfaces 812a, 812b can be terminated in a separate treatment to provide the additional species for direct bonding. In various embodiments, the terminating species can comprise nitrogen. For example, in some embodiments, the bonding surface(s) 812a, 812b can be exposed to a nitrogen-containing plasma. Other terminating species can be suitable for improving bonding energy, depending upon the materials of the bonding surfaces 812a, 812b. Further, in some embodiments, the bonding surface(s) 812a, 812b can be exposed to fluorine. For example, there may be one or multiple fluorine concentration peaks at or near a bond interface 818 between the first and second elements 802, 804. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 800, the bond interface 818 between two non-conductive materials (e.g., the bonding layers 808a, 808b) can comprise a very smooth interface with higher nitrogen (or other terminating species) content and/or fluorine concentration peaks at the bond interface 818. In some embodiments, the nitrogen and/or fluorine concentration peaks may be detected using various types of inspection techniques, such as SIMS techniques. The polished bonding surfaces 812a and 812b can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 808a and 808b can be directly bonded to one another without an adhesive. In some embodiments, the elements 802, 804 are brought together at room temperature, without the need for application of a voltage, and without the need for application of external pressure or force beyond that used to initiate contact between the two elements 802, 804. Contact alone can cause direct bonding between the non-conductive surfaces of the bonding layers 808a, 808b (e.g., covalent dielectric bonding). Subsequent annealing of the bonded structure 800 can cause the conductive features 806a, 806b to directly bond.

In some embodiments, prior to direct bonding, the conductive features 806a, 806b are recessed relative to the surrounding field regions, such that a total gap between opposing contacts after dielectric bonding and prior to anneal is less than 15 nm, or less than 10 nm. Because the recess depths for the conductive features 806a and 806b can vary across each element, due to process variation, the noted gap can represent a maximum or an average gap between corresponding conductive features 806a, 806b of two joined elements (prior to anneal). Upon annealing, the conductive features 806a and 806b can expand and contact one another to form a metal-to-metal direct bond.

During annealing, the conductive features 806a, 806b (e.g., metallic material) can expand while the direct bonds between surrounding non-conductive materials of the bonding layers 808a, 808b resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 806a, 806b can comprise discrete pads, contacts, electrodes, or traces at least partially embedded in the non-conductive field regions of the bonding layers 808a, 808b. In some embodiments, the conductive features 806a, 806b can comprise exposed contact surfaces of TSVs (e.g., through silicon vias).

As noted above, in some embodiments, in the elements 802, 804 of FIG. 1A prior to direct bonding, portions of the respective conductive features 806a and 806b can be recessed below the non-conductive bonding surfaces 812a and 812b, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 806a, 806b or to average depths of the recesses relative to local non-conductive field regions. Even for an individual conductive feature 806a, 806b, the vertical recess can vary across the feature, and so can be measured at or near the lateral middle or center of the cavity in which a given conductive feature 806a, 806b is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 806a, 806b across the direct bond interface 818 (e.g., small or fine pitches for regular arrays).

In some embodiments, a pitch p of the conductive features 806a, 806b, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 806a and 806b to one of the lateral dimensions (e.g., a diameter) of the bonding pad is less than is less than 20, or less than 10, or less than 5, or less than 3 and sometimes desirably less than 2. In various embodiments, the conductive features 806a and 806b and/or traces can comprise copper or copper alloys, although other metals may be suitable, such as nickel, aluminum, or alloys thereof. The conductive features disclosed herein, such as the conductive features 806a and 806b, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 802, 804, as shown, the orientations of one or more conductive features 806a, 806b from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 806b in the bonding layer 808b (and/or at least one internal conductive feature, such as a BEOL feature) of the upper element 804 may be tapered or narrowed upwardly, away from the bonding surface 812b. By way of contrast, at least one conductive feature 806a in the bonding layer 808a (and/or at least one internal conductive feature, such as a BEOL feature) of the lower element 802 may be tapered or narrowed downwardly, away from the bonding surface 812a. Similarly, any bonding layers (not shown) on the backsides 816a, 816b of the elements 802, 804 may taper or narrow away from the backsides, with an opposite taper orientation relative to front side conductive features 806a, 806b of the same element.

As described above, in an anneal phase of hybrid bonding, the conductive features 806a, 806b can expand and contact one another to form a metal-to-metal direct bond. In some embodiments, the materials of the conductive features 806a, 806b of opposite elements 802, 804 can interdiffuse during the annealing process. In some embodiments, metal grains grow into each other across the bond interface 818. In some embodiments, the metal is or includes copper, which can have grains oriented along the 811 crystal plane for improved copper diffusion across the bond interface 818. In some embodiments, the conductive features 806a and 806b may include nanotwinned copper grain structure, which can aid in merging the conductive features during anneal. There is substantially no gap between the non-conductive bonding layers 808a and 808b at or near the bonded conductive features 806a and 806b. In some embodiments, a barrier layer may be provided under and/or laterally surrounding the conductive features 806a and 806b (e.g., which may include copper). In other embodiments, however, there may be no barrier layer under the conductive features 806a and 806b.

The embodiments discussed above are intended to be illustrative and not limiting. One skilled in the art would appreciate that individual aspects of the display and display device, and methods discussed herein may be omitted, modified, combined, and/or rearranged without departing from the scope of the disclosed subject matter.

1. A display comprising:
a plurality of substrates comprising a first substrate, and a second substrate, wherein the plurality of substrates comprises a plurality of singulated LEDs embedded in a respective dielectric layer; and
a layer disposed between the first substrate and the second substrate, the layer comprising mirrors that direct light from respective LEDs of the first substrate towards a display side of the display.

2. The display of claim 1, wherein:
the first substrate is an intermediate substrate;
the second substrate is a top substrate;
the plurality of substrates further comprises a bottom substrate; and
the bottom substrate comprises a plurality of singulated LEDs embedded in a respective dielectric layer.

3. The display of claim 2, wherein the mirrors comprise a dichroic film which allows transmission of wavelengths emitted from the singulated LEDs of the bottom substrate while concurrently reflecting wavelengths emitted from the singulated LEDs of the intermediate substrate.

4. The display of claim 2, wherein:
the mirrors comprises pairs of mirrors for each corresponding LED of the intermediate substrate;
one mirror of the pair of mirrors reflects wavelengths emitted from a corresponding LED of the intermediate substrate towards another mirror of the pair of mirrors; and
the other mirror of the pair of mirrors reflects light from the one mirror towards the display side of the display and enables transmission of wavelengths emitted from a corresponding LED of the bottom substrate towards the display side on the display.

5. The display of claim 2, wherein the LEDs of the bottom substrate are offset with respect to LEDs in the intermediate and top substrates.

6. The display of claim 2, wherein:
the layer is a first layer;
the mirrors are first mirrors; and
the display further comprises:
a second layer disposed between the bottom substrate and the intermediate substrate, the second layer comprising second mirrors that direct light from respective LEDs of the bottom substrate towards the display side of the display.

7. The display of claim 6, further comprising a third layer disposed on the top substrate comprising third mirrors that direct light from LEDs of the top substrate towards the display side of the display.

8. The display of claim 6, wherein the first mirrors comprise a dichroic film which allows transmission of wavelengths emitted from the singulated LEDs of the bottom substrate while concurrently reflecting wavelengths emitted from the singulated LEDs of the intermediate substrate.

9. The display of claim 7, wherein the third mirrors comprise a dichroic film which allows transmission of wavelengths emitted from the singulated LEDs embedded in the bottom and intermediate substrates while reflecting wavelengths emitted from the singulated LEDs embedded in the top substrate.

10. The display of claim 2, further comprising a plurality of pixels each comprising at least one LED from each of the bottom, intermediate, and top substrates.

11. The display of claim 10, wherein each pixel comprises at least three LEDs that each emit a different color of light from the other.

12. The display of claim 1, further comprising a reflective layer disposed between the LEDs and the dielectric layers.

13. The display of claim 1, wherein each of the plurality of substrates is directly bonded to a vertically adjacent substrate and/or layer without use of an intervening adhesive.

14. A display comprising:
a plurality of substrates comprising a bottom substrate, an intermediate substrate, and a top substrate, wherein each of the plurality of substrates comprises a plurality of singulated LEDs embedded in a respective dielectric layer;
a first layer disposed between the intermediate substrate and the top substrate, the first layer comprising first mirrors that direct light from respective LEDs of the intermediate substrate towards a display side of the display; and
a second layer disposed between the bottom substrate and the intermediate substrate, the second layer comprising second mirrors that direct light from respective LEDs of the bottom substrate towards a display side of the display, wherein each of the first mirrors are positioned to direct light emitted from the LEDs of the intermediate substrate through a first horizontal direction and each of the second mirrors are positioned to direct light from the LEDs of the bottom substrate through a second horizontal direction orthogonal to the first horizontal direction.

15. The display of claim 14, further comprising a plurality of pixels each comprising at least one LED from each of the bottom, intermediate, and top substrates.

16. The display of claim 15, wherein each pixel comprises at least three LEDs that each emit a different color of from the other.

17. The display of claim 14, further comprising a reflective layer disposed between each LED and the dielectric layer.

18. The display of claim 14, wherein the dielectric layer comprises a dichroic filter optically tuned material wherein a transmission spectrum of the material overlaps with a respective emission spectra of the respective LED.

19. The display of claim 14, further comprising anti-reflective coatings disposed on top of the respective substrate to enhance light extraction efficiency by reducing internal reflections.

20. The display of claim 14, wherein each of plurality of substrates are directly bonded to a vertically adjacent substrate without use of an intervening adhesive.

21-28. (canceled)
